(19) United States
(12) Patent Application Publication
(10) Pub. No.: US 2014/0158191 A1
(43) Pub. Date: Jun. 12, 2014

(54) SOLAR CELL AND METHOD FOR MANUFACTURING THE SAME

(71) Applicant: Myung Seok Shim, Seoul (KR)

(72) Inventor: Myung Seok Shim, Seoul (KR)

(73) Assignee: LG INNOTEK CO., LTD., Seoul (KR)

(21) Appl. No.: 14/235,813

(22) PCT Filed: May 23, 2012
(86) PCT No.: PCT/KR2012/004056

§ 371 Date: Jan. 29, 2014

(30) Foreign Application Priority Data
Jul. 29, 2011 (KR) 10-2011-0076280

(51) Int. Cl. H01L 31/065; H01L 31/068; H01L 31/18

(52) U.S. Cl. CPC H01L 31/065; H01L 31/1884; H01L 31/068
USPC 136/255; 438/98; 136/252; 136/262

(57) ABSTRACT

A solar cell includes a substrate; a back electrode layer provided on the substrate; a light absorbing layer provided on the back electrode layer; a transparent electrode layer provided on the light absorbing layer; and an impurity doping layer provided between the light absorbing layer and the transparent electrode layer. In the solar cell, contact resistance during contact of the transparent electrode layer with the back electrode layer is reduced by making an impurity doping amount of the impurity doping layer greater than that of the transparent electrode layer.

### TECHNICAL FIELD

The embodiment relates to a solar cell and a method for manufacturing the same. More particularly, the embodiment relates to a solar cell having an improved efficiency and a method for manufacturing the same.

### BACKGROUND ART

In general, a solar cell converts solar energy into electrical energy. Recently, as energy consumption is increased, the solar cell has been extensively used commercially.

The solar cell can be formed by laminating a back electrode layer, a light absorbing layer, and a transparent electrode layer on a transparent glass substrate in such a manner that the back electrode layer can be electrically connected to the transparent electrode layer.

However, when connecting the back electrode layer to the transparent electrode layer, contact resistance is increased between the back electrode layer and the transparent electrode layer, deteriorating the efficiency of the solar cell.

### DISCLOSURE OF INVENTION

### Technical Problem

The embodiment provides a solar cell capable of reducing contact resistance between a back electrode layer and a transparent electrode layer and a method for manufacturing the same.

### Solution to Problem

According to the embodiment, there is provided a solar cell including: a substrate; a back electrode layer on the substrate; a light absorbing layer on the back electrode layer; and an impurity doping layer between the light absorbing layer and the transparent electrode layer.

According to the embodiment, there is provided a method for manufacturing a solar cell including the steps of preparing a substrate; forming a back electrode layer on the substrate; forming a light absorbing layer on the back electrode layer; forming an impurity doping layer on the light absorbing layer; and forming a transparent electrode layer on the impurity doping layer.

### Advantageous Effects of Invention

According to the embodiment, an impurity doping layer may be formed in a lower portion of a transparent electrode layer to increase an electron collecting efficiency, thereby improving current characteristics of the solar cell.

Further, according to the embodiment, contact resistance between the back electrode layer and the transparent electrode layer may be reduced by making a doping amount of the impurity doping layer greater than that of the transparent electrode layer.

In addition, according to the embodiment, contact resistance between the back electrode and the transparent electrode layer may be reduced by making an impurity doping amount of the impurity doping layer greater than that of the transparent electrode layer.

### BRIEF DESCRIPTION OF DRAWINGS

FIG. 1 is a sectional view showing a solar cell according to the embodiment;

FIG. 2 is a sectional view showing a modified example of a solar cell according to the embodiment; and

FIGS. 3 to 8 are sectional views showing a method for manufacturing the solar cell according to the embodiment.

### MODE FOR THE INVENTION

Embodiments will be described below in more detail with reference to the accompanying drawings.

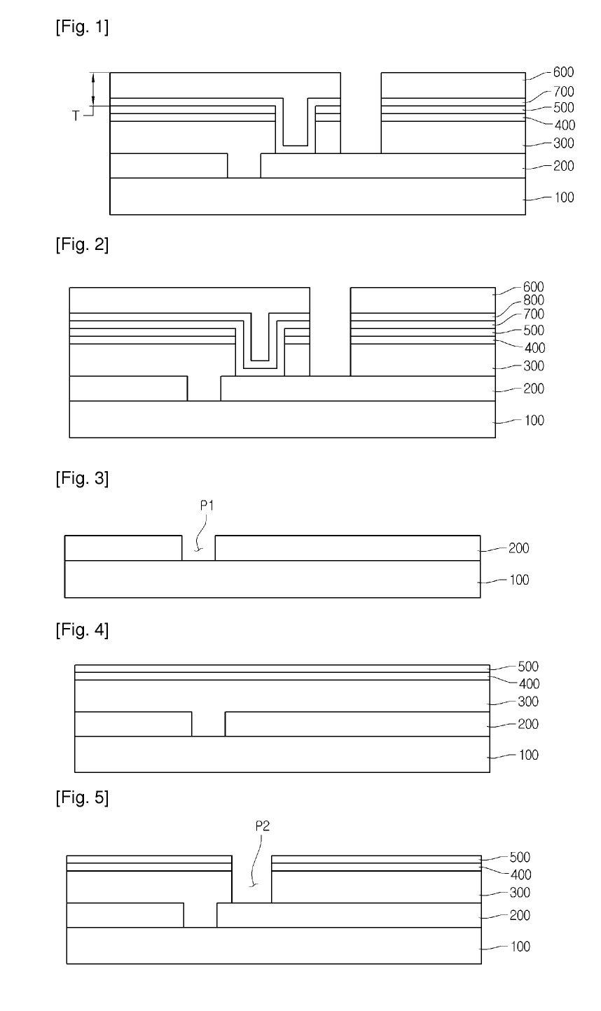

FIG. 1 is a sectional view showing a solar cell according to the embodiment, and FIG. 2 is a sectional view showing a modified example of a solar cell according to the embodiment.

Referring to FIG. 1, the solar cell according to the embodiment includes a substrate 100, a back electrode layer 200 on the substrate 100, a light absorbing layer 300 on the back electrode layer 200, a first buffer layer 400 and a second buffer layer 500 on the light absorbing layer 300, a transparent electrode layer 600 on the second buffer 500, and an impurity doping layer 700 between the light absorbing layer 300 and the transparent electrode layer 600.

The substrate 100 may have a plate shape and include a transparent glass material.

The substrate 100 may be rigid or flexible. A plastic substrate or a metal substrate may be used in addition to a glass substrate as the substrate 100. Further, a soda lime glass substrate with a sodium component may be used as the substrate 100.

The back electrode layer 200 may be formed on the substrate 100.

The back electrode layer 200 may include molybdenum (Mo). The back electrode layer 200 may include metal such as aluminum (Al), nickel (Ni), chromium (Cr), titanium (Ti), silver (Ag), or gold (Au) in addition to the Mo or a transparent conductive oxide (TCO) film such as indium tin oxide (ITO), zinc oxide (ZnO), or SnO₂.

The back electrode layer 200 may be formed to provide at least two layers using homogeneous or heterogeneous metal.

The light absorbing layer 300 may be formed on the back electrode layer 200.

The light absorbing layer 300 may have a group I-III-VI compound. For example, the light absorbing layer 300 may have the CIGSS (Cu(IN,Ga)Se₂) crystal structure, the CISS (Cu(IN)(Se,S)₂) crystal structure or the CGSS (Cu(Ga)(Se,S)₂) crystal structure.

The first buffer layer 400 may be formed on the the light absorbing layer 300.

The first buffer layer 400 makes direct contact with the light absorbing layer 300 on the light absorbing layer 300, and functions to attenuate an energy gap between the light absorbing layer 300 and the transparent electrode layer 600 to be described below.

The first buffer layer 400 may be formed by using a material including cadmium sulfide (CdS), and may have an energy bandgap corresponding to the intermediate energy bandgap between the back electrode layer 200 and the transparent electrode layer 600.

The second buffer layer 500 may be formed on the first buffer layer 400.

The second buffer layer 500 is a high resistance buffer layer and may include zinc oxide (ZnO) having high light transmittance and electric conductivity.

The second buffer layer 500 may prevent insulation from the transparent electrode layer 600 and attenuate shock damage.

An impurity doping layer 700 and the transparent electrode layer 600 according to the embodiment may be sequentially formed on the second buffer layer 500.

Each of the impurity doping layer 700 and the transparent electrode layer 800 may have a thickness T in a range of 100 nm to 2000 nm.

The transparent electrode layer 600 includes a transparent conductive material, or may include aluminum doped zinc oxide (AZO; ZnO:Al) serving as an impurity.

The transparent electrode layer 600 may be formed by using one of zinc oxide (ZnO), SnO₂, and ITO having high light transmittance and electric conductivity as well as the AZO.

The impurity doping layer 700 according to the embodiment may be directly deposited on the light absorbing layer 300.

The impurity doping layer 700 may be formed by using a material including a group III element, for example, aluminum (Al), boron (B), gallium (Ga), or Indium (In).

The group III element is the most ideal material capable of easily increasing a free charge density of a zinc oxide (ZnO) nano structure, and the content of impurities in the group III element may be greater than the content of impurities doped in the transparent electrode layer 600.

Accordingly, an electron collecting efficiency in the transparent electrode layer 600 is improved in comparison with the related art such that current characteristics of the solar cell may be improved.

Further, because an impurity doping amount of the impurity doping layer 700 is greater than that of the transparent electrode layer 600, contact resistance may be reduced during contact of the transparent electrode layer 600 with the back electrode layer 200.

Although the impurity doping layer 700 having a single-layer structure is formed in the forgoing embodiment, the embodiment is not limited thereto. In other words, the impurity doping layer 700 having a two-layer structure may be formed.

As shown in FIG. 2, the solar cell according to the embodiment may include a substrate 100, a back electrode layer 200, a light absorbing layer 300, a first buffer layer 400, a second buffer layer 500, and a transparent electrode layer 600, which are sequentially formed on the support substrate 100, and a plurality of impurity doping layers 700 and 800 between the light absorbing layer 300 and the transparent electrode layer 600.

The present embodiment, has the configuration the same as the configuration of the foregoing embodiment except for impurity doping layers 700 and 800, and the description about the same configuration will be omitted.

The impurity doping layers 700 and 800 may be directly formed on the light absorbing layer 300, and include a first impurity doping layer 700 and a second impurity doping layer 800.

Each of the first impurity doping layer 700 and the second impurity doping layer 800 may include a material including a group III element. For example, each of the first and second impurity doping layers 700 and 800 may include a material including aluminum (Al), boron (B), gallium (Ga), or Indium (In).

In this case, doping amounts of the first impurity doping layer 700 and the second impurity doping layer 800 may differ from each other. The doping amount of the first impurity doping layer 700 may be greater than the doping amount of the second impurity doping layer 800.

When the doping amount of the first impurity doping layer 700 becomes greater than the doping amount of the second impurity doping layer 800, an electron collecting efficiency is increased by the first impurity doping layer 700, thereby improving current characteristics.

Further, because the second impurity doping layer 800 has a doping amount less than a doping amount of the first impurity doping layer 700, light transmissivity may be improved. Accordingly, an amount of light absorbed in the light absorbing layer 300 may be further increased.

Although the foregoing embodiment has illustrated that there are two impurity doping layers, three or more impurity doping layers may be formed. When the three or more impurity doping layers are formed, doping amounts of the impurity doping layers become gradually reduced in the direction of the upper portions of the impurity doping layers.

Hereinafter, a method for manufacturing a solar cell according to an embodiment will be described in detail with reference to accompanying drawings.

FIGS. 3 to 8 are sectional views showing a method for manufacturing the solar cell according to the embodiment.

When a substrate 100 is prepared as shown in FIG. 2, a step of forming a back electrode layer 200 on the substrate 100 is performed.

The back electrode layer 200 may be formed by depositing molybdenum (Mo) using a sputtering method.

Next, a patterning process is performed to divide the back electrode layer 200 in the form of a strip, thereby forming a first pattern line P1. In this case, the patterning process may be performed using a laser.

As shown in FIG. 3, when the first pattern line P1 is formed on the back electrode layer 200, a light absorbing layer 300, a first buffer layer 400, and a second buffer layer 500 are sequentially formed on the back electrode layer 200.

The light absorbing layer 300 may be formed by depositing CIGS using co-evaporation.

The first buffer layer 400 may be formed by depositing cadmium sulfide (CdS) using Chemical Bath Deposition (CBD).

The second buffer layer 500 may be formed by sputtering zinc oxide (ZnO).

As shown in FIG. 5, when the light absorbing layer 300, the first buffer layer 400, and the second buffer layer 500 are sequentially laminated on the back electrode layer 200, a second pattern line P2 is formed in parts of the light absorbing layer 300, the first buffer layer 400, and the second buffer layer 500 by the patterning process, respectively.

The second pattern line P2 may be spaced apart from the first pattern line P1 by a predetermined distance, and the second pattern line P2 may be formed by a scribing method or a laser.

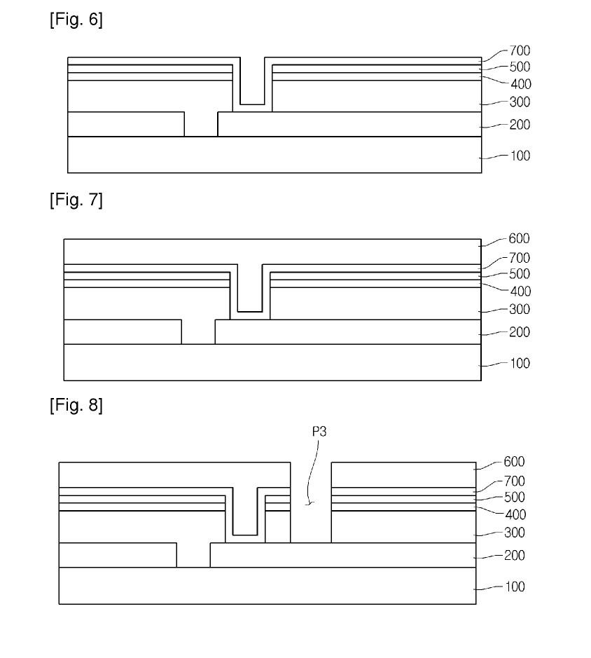

As shown in FIG. 6, when the second pattern line P2 is formed on the light absorbing layer 300, the first buffer layer 400, and the second buffer layer 500, a step of forming an impurity doping layer 700 on the second buffer layer 500 may be performed.

The impurity doping layer 700 may be formed through the CVD, sputtering, or evaporation scheme by using a group III element, for example, aluminum (Al), boron (B), gallium (Ga), or Indium (In).

As shown in FIG. 7, when the impurity doping layer 700 is formed on the second buffer 50, a step of forming a transparent electrode layer 600 on the impurity doping layer 700 is performed.

The transparent electrode layer 600 may be formed by depositing AZO using a sputtering method.

As shown in FIG. 8, when the transparent electrode layer 600 is formed on the impurity doping layer 700, a third pattern line P3 may be formed in the light absorbing layer 300, the first buffer layer 400, the second buffer layer 500, and the transparent electrode layer 600.

The third pattern line P3 may be spaced apart from the second pattern line P2 by a predetermined distance, and may be formed by a scribing method or a laser.

Accordingly, manufacturing the solar cell according to the embodiment may be completed.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a substrate;
a back electrode layer provided on the substrate;
a light absorbing layer provided on the back electrode layer;
a transparent electrode layer provided on the light absorbing layer; and
an impurity doping layer provided between the light absorbing layer and the transparent electrode layer.

2. The solar cell of claim 1, wherein the impurity doping layer includes one selected from the group consisting of aluminum (Al), boron (B), gallium (Ga), and Indium (In).

3. The solar cell of claim 1, wherein the transparent electrode layer and the impurity doping layer have a thickness in a range of 100 nm to 2000 nm.

4. The solar cell of claim 1,
wherein the impurity doping layer has a multi-layer structure, and
wherein impurity content in the impurity doping layer becomes reduced as the impurity doping layer becomes adjacent to the transparent electrode layer.

5. The solar cell of claim 1, wherein a doping amount of the impurity doping layer is greater than a doping amount of the transparent electrode layer.

6. A solar cell comprising:
a substrate;
a back electrode layer provided on the substrate;
a light absorbing layer provided on the back electrode layer;
a transparent electrode layer provided on the light absorbing layer; and
an impurity doping layer including a first impurity doping layer and a second impurity doping layer and provided between the light absorbing layer and the transparent electrode layer.

7. The solar cell of claim 6, wherein a doping amount of the first impurity doping layer and a doping amount of the second impurity doping layer differ from each other.

8. The solar cell of claim 6,
wherein the second impurity doping layer is closer to the transparent electrode layer as compared with the first impurity doping layer, and
wherein a doping amount of the second impurity doping layer is less than a doping amount of the first impurity doping layer.

9. A method for manufacturing a solar cell, the method comprising:
preparing a substrate;
forming a back electrode layer on the substrate;
forming a light absorbing layer on the back electrode layer;
forming an impurity doping layer on the light absorbing layer; and
forming a transparent electrode layer on the impurity doping layer.

10. The method of claim 9, wherein in the forming of the impurity doping layer, the impurity doping layer is formed by depositing one selected from the group consisting of aluminum (Al), boron (B), gallium (Ga), and Indium (In).

11. The method of claim 9, wherein the transparent electrode layer and the impurity doping layer have a thickness in a range of 100 nm to 2000 nm.

12. The method of claim 9, wherein the forming of the impurity doping layer includes forming a first impurity doping layer and a second impurity doping layer placed on the first impurity doping layer.

13. The method of claim 12, wherein a doping amount of the first impurity doping layer and a doping amount of the second impurity doping layer differ from each other.

14. The method of claim 12, wherein a doping amount of the second impurity doping layer is less than a doping amount of the first impurity doping layer.

15. The solar cell of claim 1, further comprising a buffer layer formed on the light absorbing layer.

16. The solar cell of claim 15, further comprising a high resistance buffer layer formed on the buffer layer.

17. The solar cell of claim 6, wherein a doping amount of the impurity doping layer is greater than a doping amount of the transparent electrode layer.

18. The method of claim 9, wherein a doping amount of the impurity doping layer is greater than a doping amount of the transparent electrode layer.
